(19) United States
(12) Patent Application Publication
(10) Pub. No.: US 2025/0338653 A1
(43) Pub. Date: Oct. 30, 2025

(54) SOLID-STATE IMAGE SENSOR

(71) Applicant: VisEra Technologies Company Limited, Hsin-Chu City (TW)

(72) Inventors: Kai-Hao CHANG, Hsin-Chu City (TW); Po-Hsiang WANG, Hsin-Chu City (TW); Chun-Yuan WANG, Hsin-Chu City (TW)

(21) Appl. No.: 18/647,681

(22) Filed: Apr. 26, 2024

(51) Int. Cl. H01L 27/146; G02B 27/42

(52) U.S. Cl. CPC H10F 39/8053; G02B 27/4205

(57) ABSTRACT

A solid-state image sensor is provided. The solid-state image sensor includes a diffraction layer and an absorption layer. The diffraction layer includes diffraction elements that have top central gaps, and the absorption layer is disposed below the diffraction layer and includes absorption elements that have bottom central gaps. Pixels of the solid-state image sensor are defined by the diffraction elements, the pixels are arranged in an array, and the absorption elements. Each top central gap corresponds to one bottom central gap and one pixel.

### BACKGROUND OF THE INVENTION

### Field of the Invention

The embodiments of the present disclosure relate to image sensors, and in particular they relate to solid-state image sensors that include a diffraction layer and an absorption layer that are stacked together for high SNR performance and high transmittance.

### Description of the Related Art

Solid-state image sensors (e.g., complementary metal-oxide semiconductor (CMOS) image sensors) have been widely used in various image-capturing apparatuses such as digital still-image cameras, digital video cameras, and the like. Signal electric charges may be generated according to the amount of light received in the light-sensing portion (e.g., the photoelectric conversion element) of the solid-state image sensor. In addition, the signal electric charges generated in the light-sensing portion may be transmitted and amplified to obtain an image signal.

Recently, the trend has been for the pixel size of image sensors typified by CMOS image sensors to be reduced for the purpose of increasing the number of pixels to provide high-resolution images. However, a thinner color filter may result in low filtering efficiency, thus reducing the sensing contrast and color performance.

### BRIEF SUMMARY OF THE INVENTION

According to the embodiments of the present disclosure, the solid-state image sensor includes a diffraction layer and an absorption layer that are stacked together to achieve high signal-to-noise ratio (SNR) performance and high transmittance. Moreover, in some embodiments, the stacked diffraction layer and absorption layer may be applied to the color filter layer of the solid-state image sensor, thereby lowering the height of the color filter layer.

An embodiment of the present invention provides a solid-state image sensor. The solid-state image sensor includes a diffraction layer and an absorption layer. The diffraction layer includes diffraction elements that have top central gaps, and the absorption layer is disposed below the diffraction layer and includes absorption elements that have bottom central gaps. Pixels of the solid-state image sensor are defined by the diffraction elements and the absorption elements. The pixels are arranged in an array. Each top central gap corresponds to one bottom central gap and one pixel.

In some embodiments, in a top view, each diffraction element or each absorption element is formed as a split cross, a hollow cross, a split rectangular grid, or a hollow rectangular block.

In some embodiments, in the top view, each diffraction element has two top horizontal portions arranged along a first direction and two top vertical portions arranged along a second direction that is perpendicular to the first direction. Each top central gap is defined by the top horizontal portions and the top vertical portions, and each top vertical portion is formed as a rectangle that has a first width in the first direction and a second width in the second direction.

In some embodiments, the first width is less than the sum of the width of each top central gap and the second width.

In some embodiments, the width of each top central gap is greater than the first width, the first width is less than the second width, a top period is defined by a distance between centers of adjacent two of the top central gaps, and a distance between centers of the top horizontal portions is from 0.60 to 0.86 top period.

In some embodiments, the width of each top central gap is greater than the first width, the first width is greater than the second width, a top period is defined by a distance between centers of adjacent two of the top central gaps, and a distance between centers of the top horizontal portions is from 0.63 to 0.77 top period.

In some embodiments, the width of each top central gap is less than the first width, the first width is less than the second width, a top period is defined by a distance between centers of adjacent two of the top central gaps, and a distance between centers of the top horizontal portions is from 0.52 to 0.91 top period.

In some embodiments, the width of each top central gap is less than the first width, the first width is greater than the second width, a top period is defined by a distance between centers of adjacent two of the top central gaps, and a distance between centers of the top horizontal portions is from 0.61 to 0.69 top period.

In some embodiments, in the top view, each absorption element has two bottom horizontal portions arranged along a first direction and two bottom vertical portions arranged along a second direction that is perpendicular to the first direction. Each bottom central gap is defined by the bottom horizontal portions and the bottom vertical portions, and each bottom vertical portion is formed as a rectangle that has a third width in the first direction and a fourth width in the second direction.

In some embodiments, the third width is less than the sum of the width of each bottom central gap and the fourth width.

In some embodiments, the width of each of the bottom central gaps is greater than the third width.

In some embodiments, the third width is less than the fourth width, a bottom period is defined by a distance between centers of adjacent two of the bottom central gaps, and a distance between centers of the bottom horizontal portions is from 0.60 to 0.71 bottom period.

In some embodiments, the third width is greater than the fourth width, a bottom period is defined by a distance between centers of adjacent two of the bottom central gaps, and a distance between centers of the bottom horizontal portions is from 0.42 to 0.77 bottom period.

In some embodiments, the width of each of the bottom central gaps is less than the third width.

In some embodiments, the third width is less than the fourth width, a bottom period is defined by a distance between centers of adjacent two of the bottom central gaps, and a distance between centers of the bottom horizontal portions is from 0.60 to 0.95 bottom period.

In some embodiments, the third width is greater than the fourth width, a bottom period is defined by a distance between centers of adjacent two of the bottom central gaps, and a distance between centers of the bottom horizontal portions is from 0.57 to 0.69 bottom period.

In some embodiments, the solid-state image sensor further includes an intermediate layer disposed between the diffraction layer and the absorption layer, wherein each of the pixels corresponds to a portion of the intermediate layer.

In some embodiments, the intermediate layer is a color filter layer, and the absorption layer is embedded in the bottom of the intermediate layer.

In some embodiments, the solid-state image sensor further includes a condensing structure disposed above the diffraction layer.

In some embodiments, the diffraction elements comprise tantalum pentoxide, and the absorption elements comprise titanium dioxide, metals, titanium, gold, silver, silicon, silicon nitride, graphene, copper, bismuth, palladium, platinum, aluminum, carbon, titanium nitride, aluminum scandium nitride, amorphous silicon, or a combination thereof.

### BRIEF DESCRIPTION OF THE DRAWINGS

The disclosure can be more fully understood from the following detailed description when read with the accompanying figures. It is worth noting that, in accordance with standard practice in the industry, various features are not drawn to scale. In fact, the dimensions of the various features may be arbitrarily increased or reduced for clarity of discussion.

FIG. 1 is a partial cross-sectional view illustrating the solid-state image sensor in accordance with some embodiments of the present disclosure.

FIG. 2A is a top view illustrating a diffraction element according to some embodiments of the present disclosure.

FIG. 2B is a top view illustrating one arrangement of multiple diffraction elements.

FIG. 2C is a top view illustrating another arrangement of multiple diffraction elements.

FIG. 3A is a top view illustrating a diffraction element according to some other embodiments of the present disclosure.

FIG. 3B is a top view illustrating one arrangement of multiple diffraction elements.

FIG. 3C is a top view illustrating another arrangement of multiple diffraction element.

FIG. 4A is a top view illustrating a diffraction element according to some other embodiments of the present disclosure.

FIG. 4B is a top view illustrating one arrangement of multiple diffraction elements.

FIG. 4C is a top view illustrating another arrangement of multiple diffraction element.

FIG. 5A is a top view illustrating a diffraction element according to some other embodiments of the present disclosure.

FIG. 5B is a top view illustrating one arrangement of multiple diffraction elements.

FIG. 5C is a top view illustrating another arrangement of multiple diffraction element.

FIG. 6A is a top view illustrating an absorption element according to some embodiments of the present disclosure.

FIG. 6B is a top view illustrating one arrangement of multiple absorption elements.

FIG. 6C is a top view illustrating another arrangement of multiple absorption elements.

FIG. 7A is a top view illustrating an absorption element according to some other embodiments of the present disclosure.

FIG. 7B is a top view illustrating one arrangement of multiple absorption elements.

FIG. 7C is a top view illustrating another arrangement of multiple absorption elements.

FIG. 8A is a top view illustrating an absorption element according to some other embodiments of the present disclosure.

FIG. 8B is a top view illustrating one arrangement of multiple absorption elements.

FIG. 8C is a top view illustrating another arrangement of multiple absorption elements.

FIG. 9A is a top view illustrating an absorption element according to some other embodiments of the present disclosure.

FIG. 9B is a top view illustrating one arrangement of multiple absorption elements.

FIG. 9C is a top view illustrating another arrangement of multiple absorption elements.

FIG. 10 is a partial cross-sectional view illustrating a solid-state image sensor in accordance with some embodiments of the present disclosure.

FIG. 11 shown transmittance spectra of the solid-state image sensor according to the comparative example and the embodiment of the present disclosure when the intermediate layer is a red color filter layer and have a thickness of about 300 nm.

FIG. 12 shows transmittance spectra of the solid-state image sensor according to the comparative example and the embodiment of the present disclosure when the intermediate layer is a green color filter layer and have a thickness of about 300 nm.

FIG. 13 shows transmittance spectra of the solid-state image sensor according to the comparative example and the embodiment of the present disclosure when the intermediate layer is a blue color filter layer and have a thickness of about 300 nm.

### DETAILED DESCRIPTION OF THE INVENTION

The following disclosure provides many different embodiments, or examples, for implementing different features of the subject matter provided. Specific examples of components and arrangements are described below to simplify the present disclosure. These are, of course, merely examples and are not intended to be limiting. For example, a first feature is formed on a second feature in the description that follows may include embodiments in which the first feature and second feature are formed in direct contact, and may also include embodiments in which additional features may be formed between the first feature and second feature, so that the first feature and second feature may not be in direct contact.

It should be understood that additional steps may be implemented before, during, or after the illustrated methods, and some steps might be replaced or omitted in other embodiments of the illustrated methods.

Furthermore, spatially relative terms, such as “beneath,” “below,” “lower,” “on,” “above,” “upper” and the like, may be used herein for ease of description to describe one element or feature's relationship to other elements or features as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the present disclosure, the terms “about,” “approximately” and “substantially” typically mean+/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. That is, when there is no specific description of the terms “about,” “approximately” and “substantially”, the stated value includes the meaning of “about,” “approximately” or “substantially”.

Unless otherwise defined, all terms (including technical and scientific terms) used herein have the same meaning as commonly understood by one of ordinary skill in the art to which this disclosure belongs. It should be understood that terms such as those defined in commonly used dictionaries should be interpreted as having a meaning that is consistent with their meaning in the context of the relevant art and will not be interpreted in an idealized or overly formal sense unless expressly so defined in the embodiments of the present disclosure.

The present disclosure may repeat reference numerals and/or letters in following embodiments. This repetition is for the purpose of simplicity and clarity and does not in itself dictate a relationship between the various embodiments and/or configurations discussed.

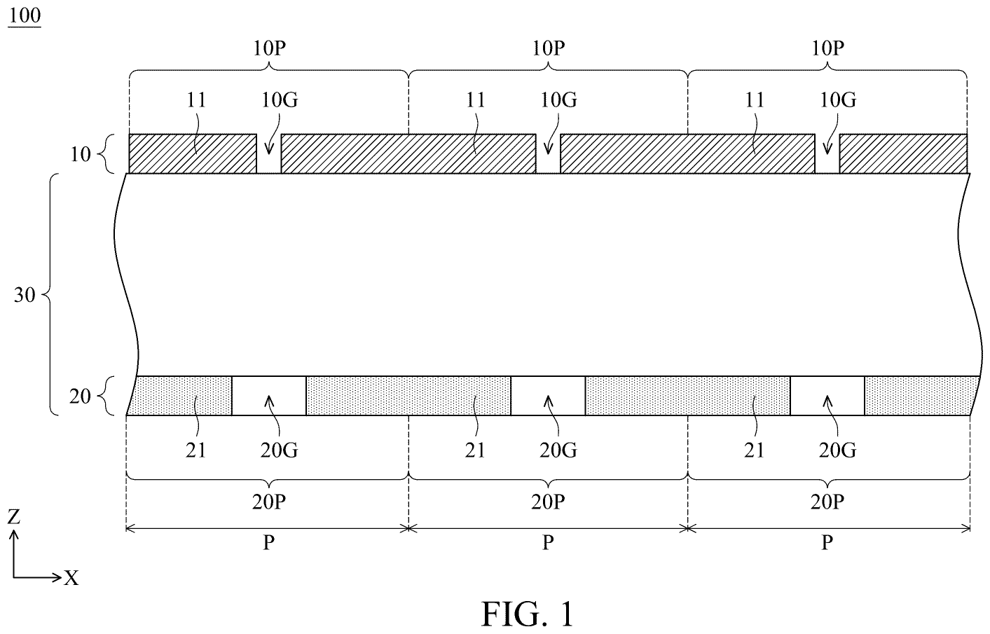

FIG. 1 is a partial cross-sectional view illustrating the solid-state image sensor 100 in accordance with some embodiments of the present disclosure. It should be noted that some components of the solid-state image sensor 100 have been omitted in FIG. 1 for the sake of brevity.

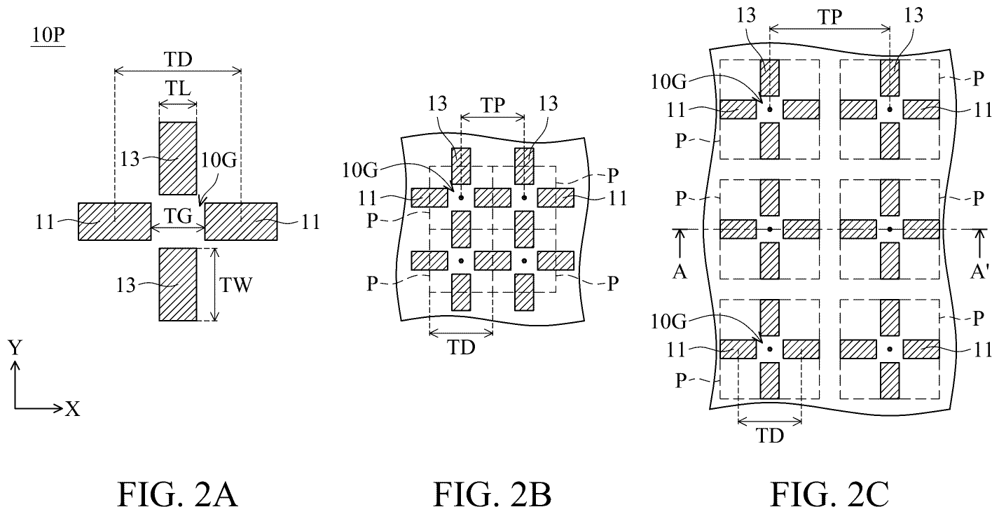

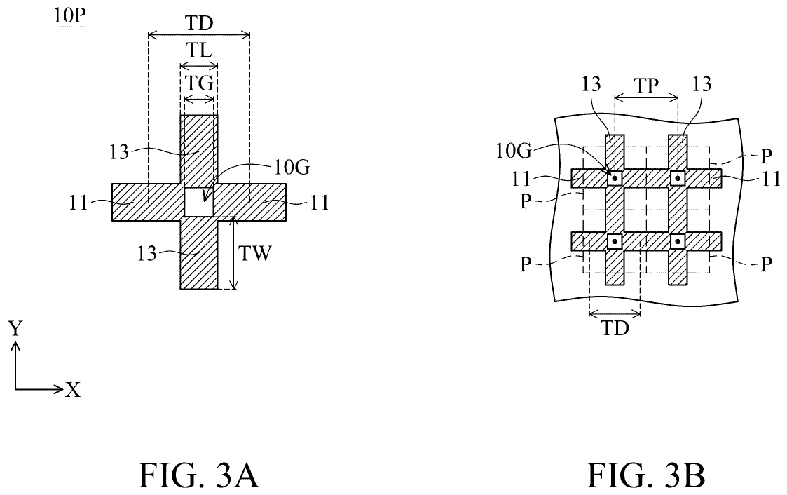

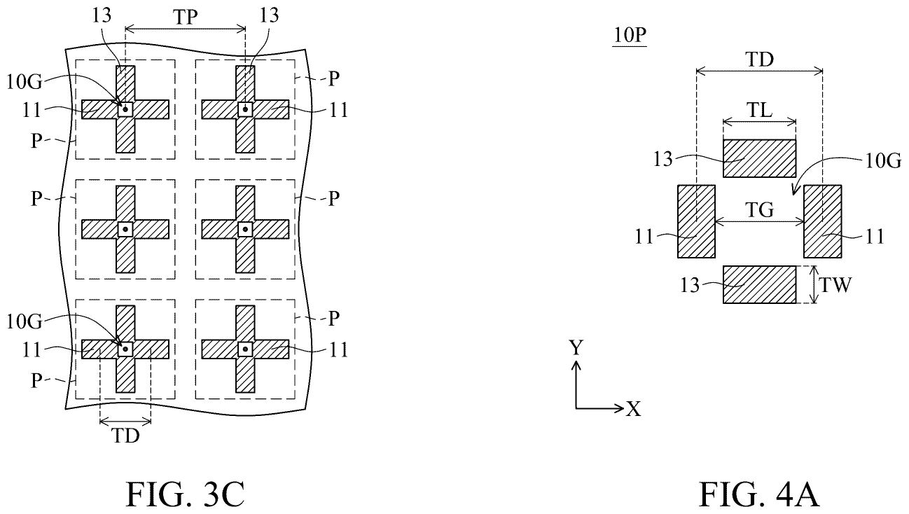

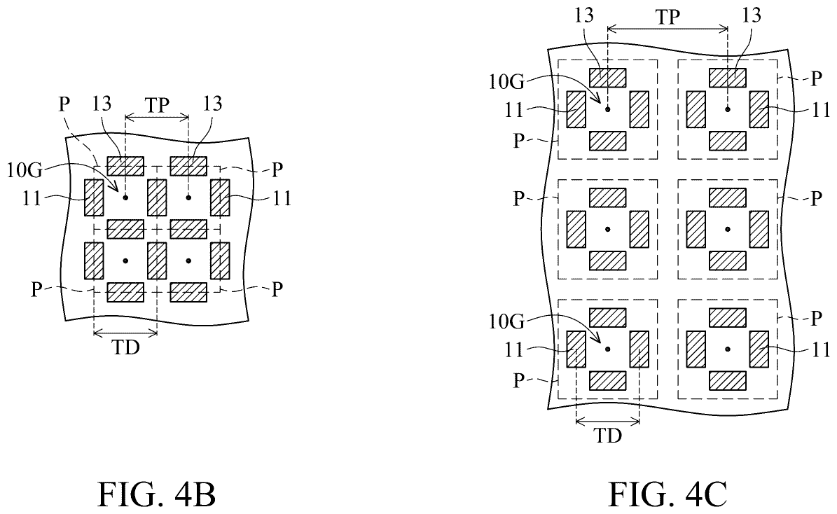

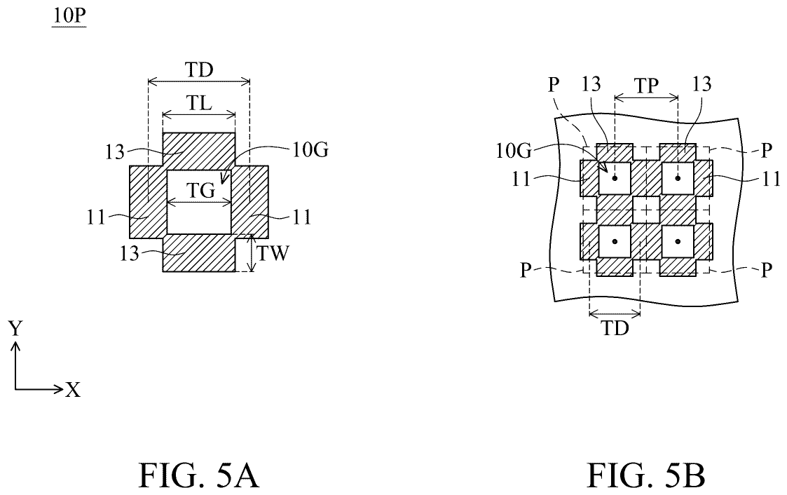

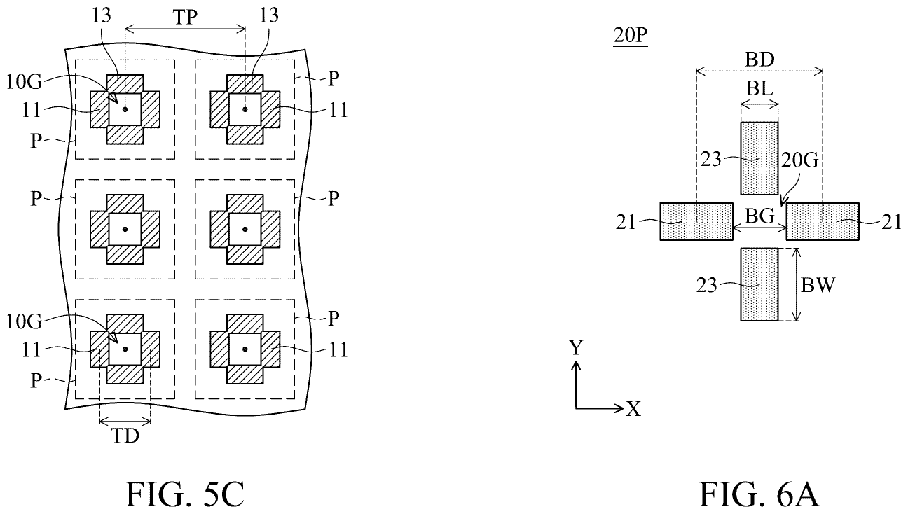

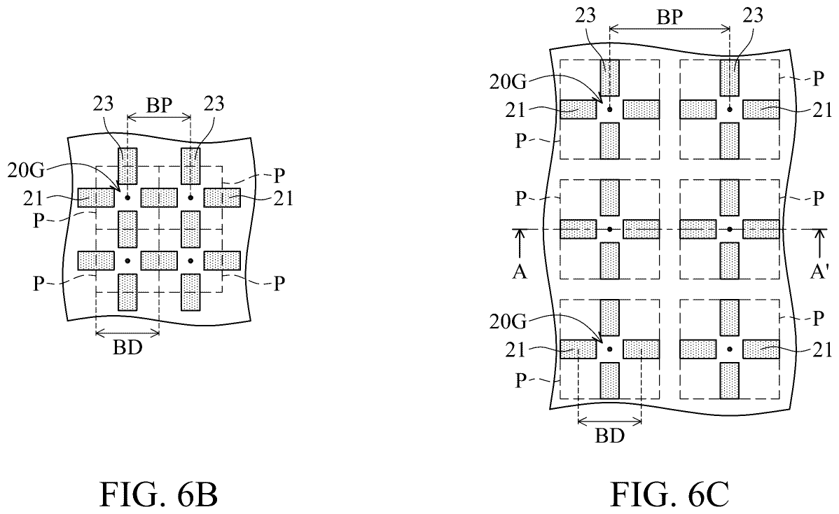

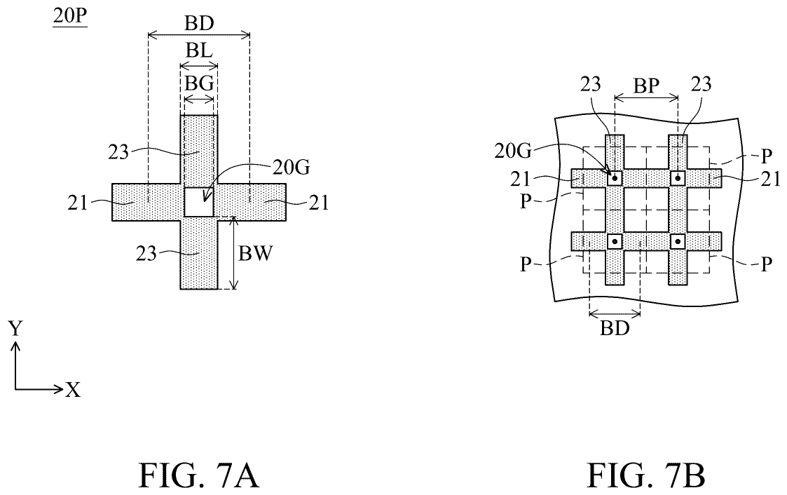

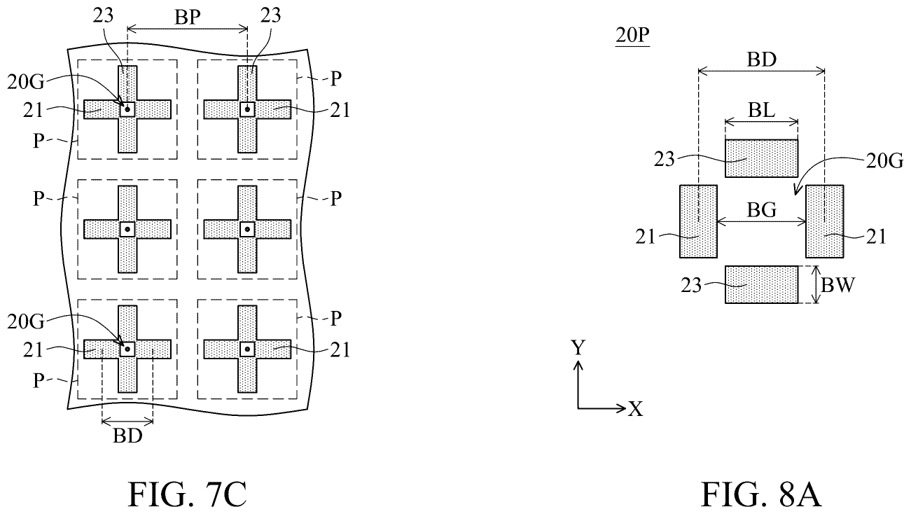

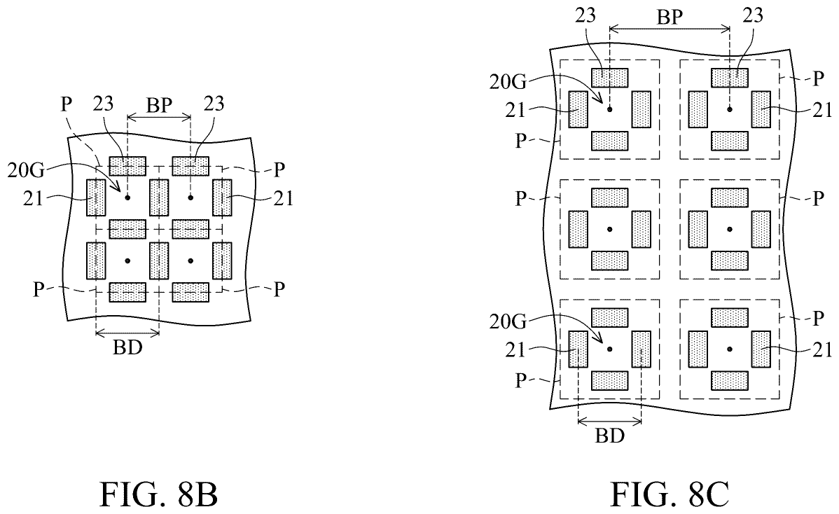

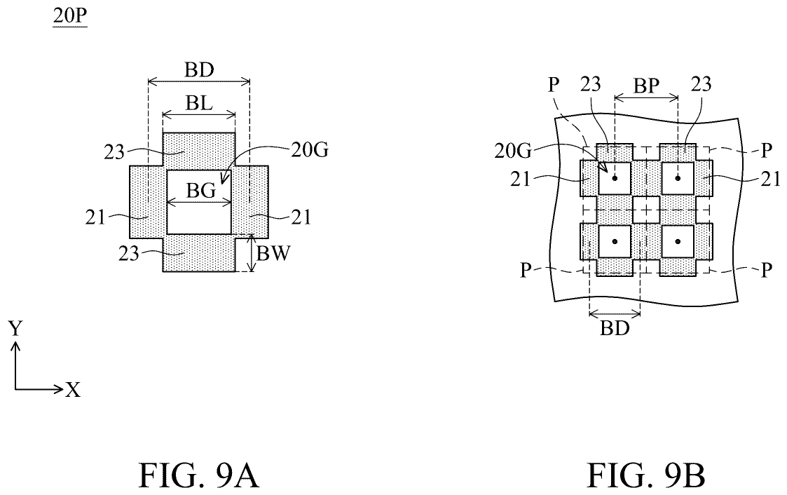

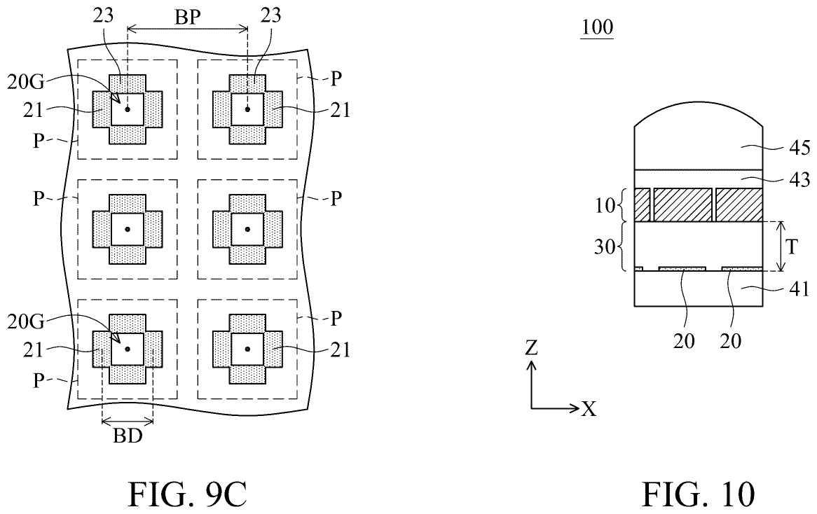

Referring to FIG. 1, in some embodiments, the solid-state image sensor 100 includes a diffraction layer 10 and an absorption layer 20 disposed below the diffraction layer. In some embodiments, the diffraction layer 10 includes diffraction elements 10P that have top central gaps 10G (also see FIG. 2A to FIG. 5A), and the absorption layer 20 includes absorption elements 20P that have bottom central gaps 20G (also see FIG. 6A to FIG. 9A). In some embodiments, pixels P of the of the solid-state image sensor 100 are defined by the diffraction elements 10P and the absorption elements 20P, and the pixels P are arranged in an array. As shown in FIG. 1 (and FIG. 2B, FIG. 2C, FIG. 3B, FIG. 3C, FIG. 4B, FIG. 4C, FIG. 5B, FIG. 5C, FIG. 6B, FIG. 6C, FIG. 7B, FIG. 7C, FIG. 8B, FIG. 8C, FIG. 9B, and FIG. 9C), each top central gap 10G corresponds to one bottom central gap 20G and one pixel P.

FIG. 2A is a top view illustrating a diffraction element 10P according to some embodiments of the present disclosure. FIG. 2B is a top view illustrating one arrangement of multiple diffraction elements 10P. FIG. 2C is a top view illustrating another arrangement of multiple diffraction elements 10P. For example, FIG. 2B shows four diffraction elements 10P that correspond to four pixels P arranged in a 2×2 array, FIG. 2C shows six diffraction elements 10P that correspond to six pixels P arranged in a 2×3 (or 3×2) array, and FIG. 1 may be a partial cross-sectional view of the solid-state image sensor 100 along line A-A′ in FIG. 2C, but the present disclosure is not limited thereto.

Referring to FIG. 2A, in this embodiment, the diffraction element 10P is formed as a split cross. In some embodiments, the diffraction element 10P includes tantalum pentoxide (TaO₅), which may have high refractive index, but the present disclosure is not limited thereto. In more detail, in this embodiment, the diffraction element 10P has two top horizontal portions 11 arranged along the X-direction and two top vertical portions 13 arranged along the Y-direction. The Y-direction is perpendicular to the X-direction. As shown in FIG. 2A, the top central gap 10G is defined by the top horizontal portions 11 and the top vertical portions 13. For example, in the top view shown in FIG. 2A, the top horizontal portions 11 are disposed on the left side and the right side of the top central gaps 10G, while the top vertical portions 13 are disposed on the upper side and the lower side of the top central gaps 10G.

As shown in FIG. 2A, in some embodiments, each top vertical portion 13 is formed as a rectangle that has a width TL in the X-direction and a width TW in the Y-direction. In this embodiment, the top horizontal portion 11 has the same shape and size as the vertical portion 13, but has a different orientation. In more detail, each top horizontal portion 11 is formed as a rectangle that has a width TL in the Y-direction and a width TW in the X-direction, but the present disclosure is not limited thereto.

In some embodiments, the width TL is less than the sum of the width TG of the top central gap 10G and the width TW. Here, the sum of the width TG of the top central gap 10G and the width TW is equal to the distance between the centers of the top horizontal portions 11 or the distance between the centers of the top vertical portions 13. Moreover, in this embodiment, the width TG of the top central gap 10G is greater than the width TL, and the width TL is less than the width TW.

As shown in FIG. 2B and FIG. 2C, in this embodiments, the top period TP is defined by the distance between the centers of two adjacent top central gaps 10G, and the distance TD between the centers of the top horizontal portions 11 (i.e., the sum of the width TG of the top central gap 10G and the width TW) is from about 0.60 to about 0.86 top period TP. Similarly, in this embodiments, the distance TD between the centers of the top vertical portions 13 (i.e., the sum of the width TG of the top central gap 10G and the width TW) is from about 0.60 to about 0.86 top period TP.

In FIG. 2B, the width TG of the top central gap 10G may be about 142 nm, the width TL may be about 125 nm, the width TW may be about 203 nm, and the distance TD between the centers of the top horizontal portions 11 (or between the centers of the top vertical portions 13) may be about 345 nm, but the present disclosure is not limited thereto.

In FIG. 2C, the width TG of the top central gap 10G may be about 75 nm, the width TL may be about 60 nm, the width TW may be about 130 nm, and the distance TD between the centers of the top horizontal portions 11 (or between the centers of the top vertical portions 13) may be about 240 nm, but the present disclosure is not limited thereto.

FIG. 3A is a top view illustrating a diffraction element 10P according to some other embodiments of the present disclosure. FIG. 3B is a top view illustrating one arrangement of multiple diffraction elements 10P. FIG. 3C is a top view illustrating another arrangement of multiple diffraction elements 10P. For example, FIG. 3B shows four diffraction elements 10P that correspond to four pixels P arranged in a 2×2 array, and FIG. 3C shows six diffraction elements 10P that correspond to six pixels P arranged in a 2×3 (or 3×2) array, but the present disclosure is not limited thereto.

Referring to FIG. 3A, in this embodiment, the diffraction element 10P is formed as a hollow cross. As shown in FIG. 3A, in some embodiments, each top vertical portion 13 is formed as a rectangle that has a width TL in the X-direction and a width TW in the Y-direction. In this embodiment, the top horizontal portion 11 has the same shape and size as the vertical portion 13, but has a different orientation. In more detail, each top horizontal portion 11 is formed as a rectangle that has a width TL in the Y-direction and a width TW in the X-direction, but the present disclosure is not limited thereto.

In some embodiments, the width TL is less than the sum of the width TG of the top central gap 10G and the width TW. Here, the sum of the width TG of the top central gap 10G and the width TW is equal to the distance between the centers of the top horizontal portions 11 or the distance between the centers of the top vertical portions 13. Moreover, in this embodiment, the width TG of the top central gap 10G is less than the width TL, and the width TL is less than the width TW. That is, a portion of the top horizontal portion 11 may overlap a portion of the top vertical portions 13.

As shown in FIG. 3B and FIG. 3C, in this embodiments, the top period TP is defined by the distance between the centers of two adjacent top central gaps 10G, and the distance TD between the centers of the top horizontal portions 11 (i.e., the sum of the width TG of the top central gap 10G and the width TW) is from about 0.52 to about 0.91 top period TP. Similarly, in this embodiments, the distance TD between the centers of the top vertical portions 13 (i.e., the sum of the width TG of the top central gap 10G and the width TW) is from about 0.52 to about 0.91 top period TP.

In FIG. 3B, the width TG of the top central gap 10G may be about 75 nm, the width TL may be about 175 nm, the width TW may be about 284 nm, and the distance TD between the centers of the top horizontal portions 11 (or between the centers of the top vertical portions 13) may be about 361 nm, but the present disclosure is not limited thereto.

In FIG. 3C, the width TG of the top central gap 10G may be about 75 nm, the width TL may be about 80 nm, the width TW may be about 130 nm, and the distance TD between the centers of the top horizontal portions 11 (or between the centers of the top vertical portions 13) may be about 210 nm, but the present disclosure is not limited thereto.

FIG. 4A is a top view illustrating a diffraction element 10P according to some other embodiments of the present disclosure. FIG. 4B is a top view illustrating one arrangement of multiple diffraction elements 10P. FIG. 4C is a top view illustrating another arrangement of multiple diffraction elements 10P. For example, FIG. 4B shows four diffraction elements 10P that correspond to four pixels P arranged in a 2×2 array, and FIG. 4C shows six diffraction elements 10P that correspond to six pixels P arranged in a 2×3 (or 3×2) array, but the present disclosure is not limited thereto.

Referring to FIG. 4A, in this embodiment, the diffraction element 10P is formed as a split rectangular grid. As shown in FIG. 4A, in some embodiments, each top vertical portion 13 is formed as a rectangle that has a width TL in the X-direction and a width TW in the Y-direction. In this embodiment, the top horizontal portion 11 has the same shape and size as the vertical portion 13, but has a different orientation. In more detail, each top horizontal portion 11 is formed as a rectangle that has a width TL in the Y-direction and a width TW in the X-direction, but the present disclosure is not limited thereto.

In some embodiments, the width TL is less than the sum of the width TG of the top central gap 10G and the width TW. Here, the sum of the width TG of the top central gap 10G and the width TW is equal to the distance between the centers of the top horizontal portions 11 or the distance between the centers of the top vertical portions 13. Moreover, in this embodiment, the width TG of the top central gap 10G is greater than the width TL, and the width TL is greater than the width TW.

As shown in FIG. 4B and FIG. 4C, in this embodiments, the top period TP is defined by the distance between the centers of two adjacent top central gaps 10G, and the distance TD between the centers of the top horizontal portions 11 (i.e., the sum of the width TG of the top central gap 10G and the width TW) is from about 0.63 to about 0.77 top period TP. Similarly, in this embodiments, the distance TD between the centers of the top vertical portions 13 (i.e., the sum of the width TG of the top central gap 10G and the width TW) is from about 0.63 to about 0.77 top period TP.

In FIG. 4B, the width TG of the top central gap 10G may be about 200 nm, the width TL may be about 180 nm, the width TW may be about 110 nm, and the distance TD between the centers of the top horizontal portions 11 (or between the centers of the top vertical portions 13) may be about 310 nm, but the present disclosure is not limited thereto.

In FIG. 4C, the width TG of the top central gap 10G may be about 175 nm, the width TL may be about 155 nm, the width TW may be about 95 nm, and the distance TD between the centers of the top horizontal portions 11 (or between the centers of the top vertical portions 13) may be about 250 nm, but the present disclosure is not limited thereto.

FIG. 5A is a top view illustrating a diffraction element 10P according to some other embodiments of the present disclosure. FIG. 5B is a top view illustrating one arrangement of multiple diffraction elements 10P. FIG. 5C is a top view illustrating another arrangement of multiple diffraction elements 10P. For example, FIG. 5B shows four diffraction elements 10P that correspond to four pixels P arranged in a 2×2 array, and FIG. 5C shows six diffraction elements 10P that correspond to six pixels P arranged in a 2×3 (or 3×2) array, but the present disclosure is not limited thereto.

Referring to FIG. 5A, in this embodiment, the diffraction element 10P is formed as a hollow rectangular block. As shown in FIG. 5A, in some embodiments, each top vertical portion 13 is formed as a rectangle that has a width TL in the X-direction and a width TW in the Y-direction. In this embodiment, the top horizontal portion 11 has the same shape and size as the vertical portion 13, but has a different orientation. In more detail, each top horizontal portion 11 is formed as a rectangle that has a width TL in the Y-direction and a width TW in the X-direction, but the present disclosure is not limited thereto.

In some embodiments, the width TL is less than the sum of the width TG of the top central gap 10G and the width TW. Here, the sum of the width TG of the top central gap 10G and the width TW is equal to the distance between the centers of the top horizontal portions 11 or the distance between the centers of the top vertical portions 13. Moreover, in this embodiment, the width TG of the top central gap 10G is less than the width TL, and the width TL is greater than the width TW. That is, a portion of the top horizontal portion 11 may overlap a portion of the top vertical portions 13.

As shown in FIG. 5B and FIG. 5C, in this embodiments, the top period TP is defined by the distance between the centers of two adjacent top central gaps 10G, and the distance TD between the centers of the top horizontal portions 11 (i.e., the sum of the width TG of the top central gap 10G and the width TW) is from about 0.61 to about 0.69 top period TP. Similarly, in this embodiments, the distance TD between the centers of the top vertical portions 13 (i.e., the sum of the width TG of the top central gap 10G and the width TW) is from about 0.61 to about 0.69 top period TP.

In FIG. 5B, the width TG of the top central gap 10G may be about 140 nm, the width TL may be about 220 nm, the width TW may be about 135 nm, and the distance TD between the centers of the top horizontal portions 11 (or between the centers of the top vertical portions 13) may be about 280 nm, but the present disclosure is not limited thereto.

In FIG. 5C, the width TG of the top central gap 10G may be about 140 nm, the width TL may be about 170 nm, the width TW may be about 105 nm, and the distance TD between the centers of the top horizontal portions 11 (or between the centers of the top vertical portions 13) may be about 245 nm, but the present disclosure is not limited thereto.

FIG. 6A is a top view illustrating an absorption element 20P according to some embodiments of the present disclosure. FIG. 6B is a top view illustrating one arrangement of multiple absorption elements 20P. FIG. 6C is a top view illustrating another arrangement of multiple absorption elements 20P. For example, FIG. 6B shows four absorption elements 20P that correspond to four pixels P arranged in a 2×2 array, FIG. 6C shows six absorption elements 20P that correspond to six pixels P arranged in a 2×3 (or 3×2) array, and FIG. 1 may be a partial cross-sectional view of the solid-state image sensor 100 along line A-A′ in FIG. 6C, but the present disclosure is not limited thereto.

Referring to FIG. 6A, in this embodiment, the absorption element 20P is formed as a split cross. In some embodiments, the absorption element 20P includes titanium dioxide, metals, titanium, gold, silver, silicon, silicon nitride, graphene, copper, bismuth, palladium, platinum, aluminum, carbon, titanium nitride, aluminum scandium nitride, amorphous silicon, or a combination thereof, but the present disclosure is not limited thereto. In more detail, in this embodiment, the absorption element 20P has two bottom horizontal portions 21 arranged along the X-direction and two bottom vertical portions 23 arranged along the Y-direction. The Y-direction is perpendicular to X-direction. As shown in FIG. 6A, the bottom central gap 20G is defined by the bottom horizontal portions 21 and the bottom vertical portions 23. For example, in the top view shown in FIG. 6A, the bottom horizontal portions 21 are disposed on the left side and the right side of the bottom central gaps 20G, while the bottom vertical portions 23 are disposed on the upper side and the lower side of the bottom central gaps 20G.

As shown in FIG. 6A, in some embodiments, each bottom vertical portion 23 is formed as a rectangle that has a width BL in the X-direction and a width BW in the Y-direction. In this embodiment, the bottom horizontal portion 21 has the same shape and size as the vertical portion 23, but has a different orientation. In more detail, each bottom horizontal portion 21 is formed as a rectangle that has a width BL in the Y-direction and a width BW in the X-direction, but the present disclosure is not limited thereto.

In some embodiments, the width BL is less than the sum of the width BG of the bottom central gap 20G and the width BW. Here, the sum of the width BG of the bottom central gap 20G and the width BW is equal to the distance between the centers of the bottom horizontal portions 21 or the distance between the centers of the bottom vertical portions 23. Moreover, in this embodiment, the width BG of the bottom central gap 20G is greater than the width BL, and the width BL is less than the width BW.

As shown in FIG. 6B and FIG. 6C, in this embodiments, the bottom period BP is defined by the distance between the centers of two adjacent bottom central gaps 20G, and the distance BD between the centers of the bottom horizontal portions 21 (i.e., the sum of the width BG of the bottom central gap 20G and the width BW) is from about 0.60 to about 0.71 bottom period BP. Similarly, in this embodiments, the distance BD between the centers of the bottom vertical portions 23 (i.e., the sum of the width BG of the bottom central gap 20G and the width BW) is from about 0.60 to about 0.71 bottom period BP.

In FIG. 6B, the width BG of the bottom central gap 20G may be about 140 nm, the width BL may be about 120 nm, the width BW may be about 145 nm, and the distance BD between the centers of the bottom horizontal portions 21 (or between the centers of the bottom vertical portions 23) may be about 285 nm, but the present disclosure is not limited thereto.

In FIG. 6C, the width BG of the bottom central gap 20G may be about 100 nm, the width BL may be about 100 nm, the width BW may be about 145 nm, and the distance BD between the centers of the bottom horizontal portions 21 (or between the centers of the bottom vertical portions 23) may be about 240 nm, but the present disclosure is not limited thereto.

FIG. 7A is a top view illustrating an absorption element 20P according to some other embodiments of the present disclosure. FIG. 7B is a top view illustrating one arrangement of multiple absorption elements 20P. FIG. 7C is a top view illustrating another arrangement of multiple absorption elements 20P. For example, FIG. 7B shows four absorption elements 20P that correspond to four pixels P arranged in a 2×2 array, and FIG. 7C shows six absorption elements 20P that correspond to six pixels P arranged in a 2×3 (or 3×2) array, but the present disclosure is not limited thereto.

Referring to FIG. 7A, in this embodiment, the absorption element 20P is formed as a hollow cross. As shown in FIG. 7A, in some embodiments, each bottom vertical portion 23 is formed as a rectangle that has a width BL in the X-direction and a width BW in the Y-direction. In this embodiment, the bottom horizontal portion 21 has the same shape and size as the vertical portion 23, but has a different orientation. In more detail, each bottom horizontal portion 21 is formed as a rectangle that has a width BL in the Y-direction and a width BW in the X-direction, but the present disclosure is not limited thereto.

In some embodiments, the width BL is less than the sum of the width BG of the bottom central gap 20G and the width BW. Here, the sum of the width BG of the bottom central gap 20G and the width BW is equal to the distance between the centers of the bottom horizontal portions 21 or the distance between the centers of the bottom vertical portions 23. Moreover, in this embodiment, the width BG of the bottom central gap 20G is less than the width BL, and the width BL is less than the width BW. That is, a portion of the bottom horizontal portion 21 may overlap a portion of the bottom vertical portions 23.

As shown in FIG. 7B and FIG. 7C, in this embodiments, the bottom period BP is defined by the distance between the centers of two adjacent bottom central gaps 20G, and the distance BD between the centers of the bottom horizontal portions 21 (i.e., the sum of the width BG of the bottom central gap 20G and the width BW) is from about 0.60 to about 0.95 bottom period BP. Similarly, in this embodiments, the distance BD between the centers of the bottom vertical portions 23 (i.e., the sum of the width BG of the bottom central gap 20G and the width BW) is from about 0.60 to about 0.95 bottom period BP.

In FIG. 7B, the width BG of the bottom central gap 20G may be about 140 nm, the width BL may be about 155 nm, the width BW may be about 240 nm, and the distance BD between the centers of the bottom horizontal portions 21 (or between the centers of the bottom vertical portions 23) may be about 380 nm, but the present disclosure is not limited thereto.

In FIG. 7C, the width BG of the bottom central gap 20G may be about 100 nm, the width BL may be about 100 nm, the width BW may be about 143 nm, and the distance BD between the centers of the bottom horizontal portions 21 (or between the centers of the bottom vertical portions 23) may be about 240 nm, but the present disclosure is not limited thereto.

FIG. 8A is a top view illustrating an absorption element 20P according to some other embodiments of the present disclosure. FIG. 8B is a top view illustrating one arrangement of multiple absorption elements 20P. FIG. 8C is a top view illustrating another arrangement of multiple absorption elements 20P. For example, FIG. 8B shows four absorption elements 20P that correspond to four pixels P arranged in a 2×2 array, and FIG. 8C shows six absorption elements 20P that correspond to six pixels P arranged in a 2×3 (or 3×2) array, but the present disclosure is not limited thereto.

Referring to FIG. 8A, in this embodiment, the absorption element 20P is formed as a split rectangular grid. As shown in FIG. 8A, in some embodiments, each bottom vertical portion 23 is formed as a rectangle that has a width BL in the X-direction and a width BW in the Y-direction. In this embodiment, the bottom horizontal portion 21 has the same shape and size as the vertical portion 23, but has a different orientation. In more detail, each bottom horizontal portion 21 is formed as a rectangle that has a width BL in the Y-direction and a width BW in the X-direction, but the present disclosure is not limited thereto.

In some embodiments, the width BL is less than the sum of the width BG of the bottom central gap 20G and the width BW. Here, the sum of the width BG of the bottom central gap 20G and the width BW is equal to the distance between the centers of the bottom horizontal portions 21 or the distance between the centers of the bottom vertical portions 23. Moreover, in this embodiment, the width BG of the bottom central gap 20G is greater than the width BL, and the width BL is greater than the width BW.

As shown in FIG. 8B and FIG. 8C, in this embodiments, the bottom period BP is defined by the distance between the centers of two adjacent bottom central gaps 20G, and the distance BD between the centers of the bottom horizontal portions 21 (i.e., the sum of the width BG of the bottom central gap 20G and the width BW) is from about 0.42 to about 0.77 bottom period BP. Similarly, in this embodiments, the distance BD between the centers of the bottom vertical portions 23 (i.e., the sum of the width BG of the bottom central gap 20G and the width BW) is from about 0.42 to about 0.77 bottom period BP.

In FIG. 8B, the width BG of the bottom central gap 20G may be about 200 nm, the width BL may be about 180 nm, the width BW may be about 110 nm, and the distance BD between the centers of the bottom horizontal portions 21 (or between the centers of the bottom vertical portions 23) may be about 310 nm, but the present disclosure is not limited thereto.

In FIG. 8C, the width BG of the bottom central gap 20G may be about 110 nm, the width BL may be about 110 nm, the width BW may be about 60 nm, and the distance BD between the centers of the bottom horizontal portions 21 (or between the centers of the bottom vertical portions 23) may be about 170 nm, but the present disclosure is not limited thereto.

FIG. 9A is a top view illustrating an absorption element 20P according to some other embodiments of the present disclosure. FIG. 9B is a top view illustrating one arrangement of multiple absorption elements 20P. FIG. 9C is a top view illustrating another arrangement of multiple absorption elements 20P. For example, FIG. 9B shows four absorption elements 20P that correspond to four pixels P arranged in a 2×2 array, and FIG. 9C shows six absorption elements 20P that correspond to six pixels P arranged in a 2×3 (or 3×2) array, but the present disclosure is not limited thereto.

Referring to FIG. 9A, in this embodiment, the absorption element 20P is formed as a hollow rectangular block. As shown in FIG. 9A, in some embodiments, each bottom vertical portion 23 is formed as a rectangle that has a width BL in the X-direction and a width BW in the Y-direction. In this embodiment, the bottom horizontal portion 21 has the same shape and size as the vertical portion 23, but has a different orientation. In more detail, each bottom horizontal portion 21 is formed as a rectangle that has a width BL in the Y-direction and a width BW in the X-direction, but the present disclosure is not limited thereto.

In some embodiments, the width BL is less than the sum of the width BG of the bottom central gap 20G and the width BW. Here, the sum of the width BG of the bottom central gap 20G and the width BW is equal to the distance between the centers of the bottom horizontal portions 21 or the distance between the centers of the bottom vertical portions 23. Moreover, in this embodiment, the width BG of the bottom central gap 20G is less than the width BL, and the width BL is greater than the width BW. That is, a portion of the bottom horizontal portion 21 may overlap a portion of the bottom vertical portions 23.

As shown in FIG. 9B and FIG. 9C, in this embodiments, the bottom period BP is defined by the distance between the centers of two adjacent bottom central gaps 20G, and the distance BD between the centers of the bottom horizontal portions 21 (i.e., the sum of the width BG of the bottom central gap 20G and the width BW) is from about 0.57 to about 0.69 bottom period BP. Similarly, in this embodiments, the distance BD between the centers of the bottom vertical portions 23 (i.e., the sum of the width BG of the bottom central gap 20G and the width BW) is from about 0.57 to about 0.69 bottom period BP.

In FIG. 9B, the width BG of the bottom central gap 20G may be about 140 nm, the width BL may be about 220 nm, the width BW may be about 135 nm, and the distance BD between the centers of the bottom horizontal portions 21 (or between the centers of the bottom vertical portions 23) may be about 280 nm, but the present disclosure is not limited thereto.

In FIG. 9C, the width BG of the bottom central gap 20G may be about 142 nm, the width BL may be about 143 nm, the width BW may be about 88 nm, and the distance BD between the centers of the bottom horizontal portions 21 (or between the centers of the bottom vertical portions 23) may be about 230 nm, but the present disclosure is not limited thereto.

It should be noted that the aforementioned diffraction element 10P and absorption element 20P may be combined in various ways. For example, the diffraction element 10P shown in FIG. 2A may be disposed above the absorption elements 20P shown in FIG. 6A, FIG. 7A, FIG. 8A, or FIG. 9A. Similarly, the diffraction element 10P shown in FIG. 3A may be disposed above the absorption elements 20P shown in FIG. 6A, FIG. 7A, FIG. 8A, or FIG. 9A. The diffraction element 10P shown in FIG. 4A may be disposed above the absorption elements 20P shown in FIG. 6A, FIG. 7A, FIG. 8A, or FIG. 9A. The diffraction element 10P shown in FIG. 5A may be disposed above the absorption elements 20P shown in FIG. 6A, FIG. 7A, FIG. 8A, or FIG. 9A.

Referring back to FIG. 1, in some embodiments, the solid-state image sensor 100 further includes an intermediate layer 30 disposed between the diffraction layer 10 and the absorption layer 20, and each pixel P corresponds to a portion of the intermediate layer 30 (i.e., FIG. 1 shows a portion of the intermediate layer 30). Moreover, in some embodiments, the absorption layer 20 is disposed on the bottom of the intermediate layer 30. In other words, the absorption layer 20 is embedded in the bottom of the intermediate layer 30, but the present disclosure is not limited thereto. In some embodiments, the intermediate layer 30 is a color filter layer. For example, the intermediate layer 30 may be a red color filter layer, a green color filter layer, or a blue color filter layer. Alternately, the intermediate layer 30 may be a yellow color filter layer, a white color filter layer, or a cyan color filter layer. In some other embodiments, there is no intermediate layer 30 disposed between the diffraction layer 10 and the absorption layer 20, and the solid-state image sensor may be applied to an IR-pass solid-state image sensor.

FIG. 10 is a partial cross-sectional view illustrating a solid-state image sensor 100 in accordance with some other embodiments of the present disclosure. It should be noted that some components of solid-state image sensor 100 have been omitted in FIG. 10 for the sake of brevity.

Referring to FIG. 10, in some embodiments, the solid-state image sensor 100 includes a semiconductor substrate 41. The semiconductor substrate 41 may be a wafer or a chip. For example, the semiconductor substrate 41 may include silicon, but the present disclosure is not limited thereto. In some embodiments, the semiconductor substrate 41 has multiple photoelectric conversion elements (not shown).

The photoelectric conversion elements 11 may be used for receiving different color lights. For example, the photoelectric conversion elements may be used for receiving red light, green light, or blue light, but the present disclosure is not limited thereto. The semiconductor substrate 41 may have other photoelectric conversion elements that may be used for receiving, for example, yellow light, white light, cyan light, or IR/NIR, which may be adjusted depending on actual needs.

Referring to FIG. 10, in some embodiments, the solid-state image sensor 100 includes an absorption layer 20 disposed above the semiconductor substrate 41 and a diffraction layer 10 disposed above the absorption layer 20. In this embodiment, the solid-state image sensor 100 also includes an intermediate layer 30 disposed between the diffraction layer 10 and the absorption layer 20. In some embodiments, the thickness T of the intermediate layer 30 is between about 200 nm and about 500 nm.

Referring to FIG. 10, in some embodiments, the solid-state image sensor 100 further includes a condensing structure 45 disposed above the diffraction layer 10. In this embodiment, the condensing structure 45 may be a micro-lens structure, such a semi-convex lens or a convex lens, but the present disclosure is not limited thereto. Moreover, the solid-state image sensor 100 includes a space layer 43 disposed between the diffraction layer 10 and the condensing structure 45.

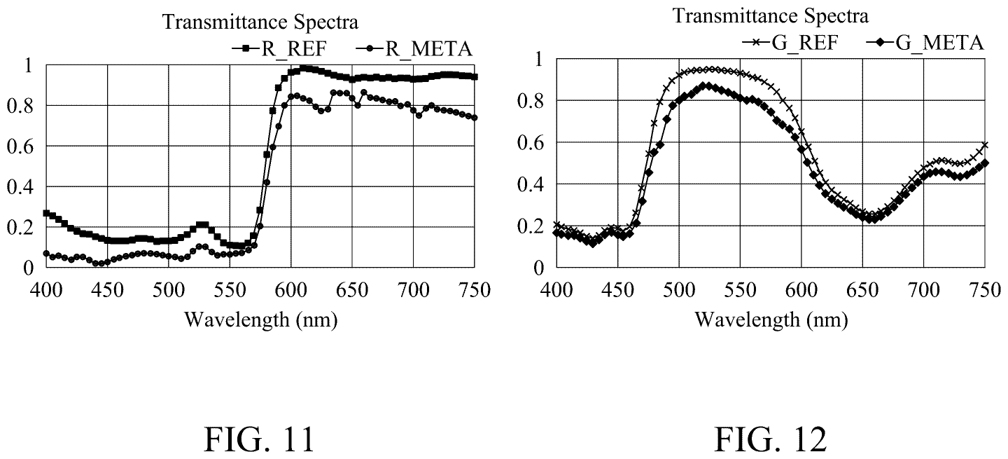

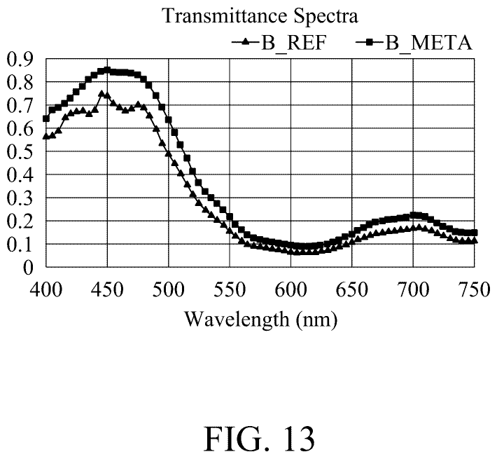

FIG. 11 shown transmittance spectra of the solid-state image sensor according to the comparative example (R_REF) and the embodiment of the present disclosure (R_META) when the intermediate layer 30 is a red color filter layer and have a thickness of about 300 nm. FIG. 12 shows transmittance spectra of the solid-state image sensor according to the comparative example (G_REF) and the embodiment of the present disclosure (G_META) when the intermediate layer 30 is a green color filter layer and have a thickness of about 300 nm. FIG. 13 shows transmittance spectra of the solid-state image sensor according to the comparative example (B_REF) and the embodiment of the present disclosure (B_META) when the intermediate layer 30 is a blue color filter layer and have a thickness of about 300 nm. Here, the solid-state image sensor according to the embodiment of the present disclosure may have a structure the same as or similar to the solid-state image sensor shown in FIG. 10, while the solid-state image sensor according to the comparative example does not include the diffraction layer 10 and the absorption layer 20

As shown in FIG. 11 to FIG. 13, compared with the solid-state image sensor according to the comparative example, the solid-state image sensor according to the embodiment of the present disclosure may have greater sensing contrast. Moreover, the solid-state image sensor according to the embodiment of the present disclosure may have improved SNR performance (e.g., enhanced by 5%) and reduced crosstalk (e.g., from 21% to 10% at 530 nm). Furthermore, the height of the color filter layer may be shortened while maintaining high color performance.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. Therefore, the scope of protection should be determined through the claims. In addition, although some embodiments of the present disclosure are disclosed above, they are not intended to limit the scope of the present disclosure.

Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the present disclosure. Thus, discussions of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the relevant art will recognize, in light of the description herein, that the disclosure can be practiced without one or more of the specific features or advantages of a particular embodiment. In other instances, additional features and advantages may be recognized in certain embodiments that may not be present in all embodiments of the disclosure.

What is claimed is:

1. A solid-state image sensor, comprising:
a diffraction layer comprising diffraction elements that have top central gaps; and
an absorption layer disposed below the diffraction layer and comprising absorption elements that have bottom central gaps;
wherein pixels of the solid-state image sensor are defined by the diffraction elements and the absorption elements, the pixels are arranged in an array, and each of the top central gaps corresponds to one of the bottom central gaps and one of the pixels.

2. The solid-state image sensor as claimed in claim 1, wherein in a top view, each of the diffraction elements or each of the absorption elements is formed as a split cross, a hollow cross, a split rectangular grid, or a hollow rectangular block.

3. The solid-state image sensor as claimed in claim 2, wherein in the top view, each of the diffraction elements has two top horizontal portions arranged along a first direction and two top vertical portions arranged along a second direction that is perpendicular to the first direction, each of the top central gaps is defined by the top horizontal portions and the top vertical portions, and each of the top vertical portions is formed as a rectangle that has a first width in the first direction and a second width in the second direction.

4. The solid-state image sensor as claimed in claim 3, wherein the first width is less than the sum of a width of each of the top central gaps and the second width.

5. The solid-state image sensor as claimed in claim 3, wherein a width of each of the top central gaps is greater than the first width, the first width is less than the second width, a top period is defined by a distance between centers of adjacent two of the top central gaps, and a distance between centers of the top horizontal portions is from 0.60 to 0.86 top period.

6. The solid-state image sensor as claimed in claim 3, wherein a width of each of the top central gaps is greater than the first width, the first width is greater than the second width, a top period is defined by a distance between centers of adjacent two of the top central gaps, and a distance between centers of the top horizontal portions is from 0.63 to 0.77 top period.

7. The solid-state image sensor as claimed in claim 3, wherein a width of each of the top central gaps is less than the first width, the first width is less than the second width, a top period is defined by a distance between centers of adjacent two of the top central gaps, and a distance between centers of the top horizontal portions is from 0.52 to 0.91 top period.

8. The solid-state image sensor as claimed in claim 3, wherein a width of each of the top central gaps is less than the first width, the first width is greater than the second width, a top period is defined by a distance between centers of adjacent two of the top central gaps, and a distance between centers of the top horizontal portions is from 0.61 to 0.69 top period.

9. The solid-state image sensor as claimed in claim 2, wherein in the top view, each of the absorption elements has two bottom horizontal portions arranged along a first direction and two bottom vertical portions arranged along a second direction that is perpendicular to the first direction, each of the bottom central gaps is defined by the bottom horizontal portions and the bottom vertical portions, and each of the bottom vertical portions is formed as a rectangle that has a third width in the first direction and a fourth width in the second direction.

10. The solid-state image sensor as claimed in claim 9, wherein the third width is less than the sum of a width of each of the bottom central gaps and the fourth width.

11. The solid-state image sensor as claimed in claim 9, wherein a width of each of the bottom central gaps is greater than the third width.

12. The solid-state image sensor as claimed in claim 11, wherein the third width is less than the fourth width, a bottom period is defined by a distance between centers of adjacent two of the bottom central gaps, and a distance between centers of the bottom horizontal portions is from 0.60 to 0.71 bottom period.

13. The solid-state image sensor as claimed in claim 11, wherein the third width is greater than the fourth width, a bottom period is defined by a distance between centers of adjacent two of the bottom central gaps, and a distance between centers of the bottom horizontal portions is from 0.42 to 0.77 bottom period.

14. The solid-state image sensor as claimed in claim 9, wherein a width of each of the bottom central gaps is less than the third width.

15. The solid-state image sensor as claimed in claim 14, wherein the third width is less than the fourth width, a bottom period is defined by a distance between centers of adjacent two of the bottom central gaps, and a distance between centers of the bottom horizontal portions is from 0.60 to 0.95 bottom period.

16. The solid-state image sensor as claimed in claim 15, wherein the third width is greater than the fourth width, a bottom period is defined by a distance between centers of adjacent two of the bottom central gaps, and a distance between centers of the bottom horizontal portions is from 0.57 to 0.69 bottom period.

17. The solid-state image sensor as claimed in claim 1, further comprising:
an intermediate layer disposed between the diffraction layer and the absorption layer, wherein each of the pixels corresponds to a portion of the intermediate layer.

18. The solid-state image sensor as claimed in claim 17, wherein the intermediate layer is a color filter layer, and the absorption layer is embedded in the bottom of the intermediate layer.

19. The solid-state image sensor as claimed in claim 1, further comprising:
a condensing structure disposed above the diffraction layer.

20. The solid-state image sensor as claimed in claim 1, wherein the diffraction elements comprise tantalum pentoxide, and the absorption elements comprise titanium dioxide, metals, titanium, gold, silver, silicon, silicon nitride, graphene, copper, bismuth, palladium, platinum, aluminum, carbon, titanium nitride, aluminum scandium nitride, amorphous silicon, or a combination thereof.
